(19) United States
(12) Patent Application Publication
(10) Pub. No.: US 2024/0247447 A1
(43) Pub. Date: Jul. 25, 2024

(54) PAVER WITH SOLAR PANEL

(71) Applicant: SUNPAVE INC, Newark, DE (US)

(72) Inventors: Abdellatif Azmy Islam Gowaid, Newark (DE); IBRAHIM ELSEROGY, Newark, TX (US); FOUAD ALGAMMAL MOHAMMAD, Newark, DE (US); ABDELHAMID AZZA FAYAD, Newark, DE (US)

(21) Appl. No.: 17/769,597

(22) PCT Filed: Oct. 19, 2020
(86) PCT No.: PCT/IB2020/059818

§ 371 Date: Apr. 15, 2022

(30) Foreign Application Priority Data
Oct. 17, 2019 (GB) 1915051.5

(51) Int. Cl. E01C 5/00; E01B 26/00; H02S 20/21; H02S 40/34

(52) U.S. Cl. CPC E01C 5/00; E01B 26/00; H02S 20/21; H02S 40/34

(57) ABSTRACT

A solar paving module (200) is described. The module (200) comprises: a frame (234); a power generating element (216) comprising at least one photovoltaic element (216) supported in the frame (234); a light transmitting surface screen (218) covering the electrical power generating element (216) and having a planar upper surface; and an electrical connector connected electrically to the power generating element (216). The solar paving module (200) comprises a heat sink (260) in thermal connectivity with the power generating element (216), the heat sink comprising a heat sink plate (262) and one or more ground plates (280) connected to the heat sink plate (262) and forming a heat sink anchor.

### FIELD OF THE INVENTION

This invention relates to modular flooring units which incorporate solar panels for generating electrical power when subject to sunlight, and in particular to pavers which incorporate solar panels and which can be used in areas subject to pedestrian and/or vehicle loading.

### BACKGROUND OF THE INVENTION

Domestic solar power technology generally uses photovoltaic (PV) cells and is limited to rooftops and spaces where no access is normally required for other purposes. On a commercial scale, there exist a number of photovoltaic products suitable for mounting on sloping or flat roofs. PV tiles are known for use in roof construction.

Some attempts have been made to provide solar power devices for trafficable surfaces. US2005/0199282 discloses a roadway panel which has a solar energy collector beneath a layer of translucent and protective material which can withstand pedestrian and vehicular traffic loading and has sufficient friction in its upper surface to allow passage of pedestrians and vehicles without slippage. The roadway panel can be modularly connected to other similar panels. However energy harvest is reduced as horizontal panels receive limited direct sunlight, and hence operate at reduced efficiency. Furthermore the panel requires a compromise between toughness and translucence. US2010/0263296 discloses a flooring module with a load bearing floor on one surface and a photovoltaic cell on an opposite surface. The module can function either as a floor in a first position when the floor surface is uppermost or as an electrical generator in the second position when the photovoltaic cell is uppermost. However the panel is not capable of serving as both a load bearing floor and an electrical generator in the same position.

It is an object of the invention to provide a solar paving module and a paving construction utilising solar paving module that overcome one or more of the above disadvantages.

### SUMMARY OF THE INVENTION

According to a first aspect of the present invention there is provided a solar paving module comprising:
a frame,
a power generating element comprising at least one photovoltaic element supported in the frame,
a light transmitting surface screen covering the electrical power generating element and having a planar upper surface, and
an electrical connector connected electrically to the power generating element,
wherein the solar paving module comprises a heat sink in thermal connectivity with the power generating element, the heat sink comprising a heat sink plate and one or more ground plates connected to the heat sink plate and forming a heat sink anchor.

The one or more ground plates may extend beyond the frame.

A portion of the heat sink, for example, one or more ground plates, may extend beyond the frame, for example, beyond the base of the frame. For example, a portion of the ground plate may be disposed within the frame, and a portion may extend beyond the plane of the base of the frame, optionally so that the extending portion can extend below the frame. This permits the extending portion to exchange heat with a substrate outside the frame, e.g. the ground or a railway sleeper for example.

The heat sink plate may be substantially parallel to the planar upper surface of the light transmitting surface screen and the one or more ground plates may extend substantially perpendicular to the heat sink plate.

Optionally two ground plates are provided and the extending portions of the ground plates may be connected (or optionally integrally formed) with the heat sink plate in a C-shaped arrangement, with spaced apart portions of the heat sink plate connected to or integrally formed with respective ground plates extending therefrom.

The heat sink plate and the one or more ground plates may be a single folded plate of heat conducting material. The material may be metallic or non-metallic, or a mixture thereof. Optionally, the single folded plate may be of steel, aluminium or an alloy thereof.

Alternatively the heat sink plate and/or the one or more ground plates may comprise one or more metal mesh panels, for example steel mesh. The heat sink plate which is substantially parallel to the planar upper surface may comprise a metal mesh panel, for example steel mesh, and the one or more ground plates which extend substantially perpendicular to the heat sink plate may each comprise an upper metal mesh panel portion and a lower plate portion.

The heat sink plate and the one or more ground plates may be integrally formed as a single piece.

The one or more ground plates may be two ground plates, and each of the ground plates may depend from sides of the heat sink plate.

The single piece may be C-shaped or omega-shaped when viewed in cross-section.

The heat sink may comprise a shaft, the shaft extending perpendicularly from the heat sink plate towards the power generating element.

The power generating element may comprise one or more elements of monocrystalline, polycrystalline, amorphous, single-junction, multi-junction, silicon-based, cadmium telluride based, quantum dots-based, and concentrated photovoltaic elements.

The frame may enclose the power generating element and at least a portion or the entirety of the screen, wherein an underside of the frame comprises a first interlocking member arranged to interlock with a second interlocking member provided on an upper surface of the heat sink plate.

The first interlocking member is arranged to releasably interlock with the second interlocking member.

The electrical connector may be provided on an underside of the heat sink plate, wherein the first and second interlocking members are arranged such that when they are interlocked the power generating element is electrically connected to the electrical connector, wherein the first and second interlocking members are arranged such that when they are not interlocked the power generating element is not electrically connected to the electrical connector.

The first interlocking member may be a recess provided on the underside of the frame and the second interlocking member may be a projection provided on the upper surface of the heat sink plate, which is receivable in the recess, wherein the recess and projection are arranged such that the power generating element becomes electrically connected to the electrical connection when the projection is received inside the recess.

The light transmitting surface screen may be releasably attached to the frame by one of a threaded fastener arrangement and a snap fit arrangement.

The power generating element may be provided on top of a thermally conductive layer, which comprises a metallic material.

A support layer may be provided intermediate the thermally conductive layer and the power generating element. The support layer may comprise silicone and optionally an additive for improving the thermal conductivity of the support layer.

The power generating element, support layer and thermally conductive layer may be formed as one entity, which is releasably attached to the frame by way of one or more mechanical fasteners. Optionally the surface screen is formed as part of the same entity.

The additive may comprise one or more of: carbon based particles; ceramic particles; and metallic particles.

The support layer may comprise: a central supporting portion, which supports the photovoltaic element, and optionally comprises silicone and optionally the additive for improving the thermal conductivity of the support layer; and a polymer surround portion surrounding the central supporting portion, which comprises a polymer and optionally the additive for improving the thermal conductivity of the support layer.

The photovoltaic element may be a monofacial solar cell.

The light transmitting surface screen may comprise a transparent polymer such as epoxy.

The electrical power generating element may be encapsulated by the surface screen. The photovoltaic element may be a monofacial photovoltaic element, and the encapsulation may be on the upper side of the photovoltaic element only. The monofacial photovoltaic element may rest on a heat conducting support surface. The photovoltaic element may be a bifacial photovoltaic element, and the encapsulation may be on both the upper and lower sides of the photovoltaic element. The portion of the surface screen below the photovoltaic element may rest on a support surface, which may be heat conducting.

The frame may comprise a frame recess, in which the power generating element and surface screen are located, and a border surrounding the recess, wherein the upper surface of the border is substantially coplanar with the upper surface of the surface screen.

The frame may be polygonal in plan, for example a regular hexagon, a rectangle or a square. The frame may be irregular in plan, for example having a perimeter comprising a plurality of straight sides and a plurality of curved sides.

The frame may be of concrete, other cementitious material, plastic, recycled plastic, polyurethane, fiberglass or a mixture thereof. The frame may be reinforced with steel or glass reinforced plastic or other reinforcing material. Relatively light-weight polyurethane or fiberglass may optionally be used to form the frame, and can be especially advantageous in certain circumstances, for example, when the paving module is installed on a marine vessel deck.

The surface screen may be circular or polygonal in plan, for example a regular hexagon, a rectangle or a square. The surface screen may be irregular in plan, for example having a perimeter comprising a plurality of straight sides and a plurality of curved sides.

The at least one photovoltaic element may comprise at least one substantially planar solar cell oriented in a tilted plane which is tilted relative to the planar upper surface of the light transmitting surface screen.

The tilted plane may be tilted at an angle of between 15 and 45 degrees relative to the planar upper surface of the light transmitting surface screen.

The surface screen and the power generating element may be part of a tracking disc which is circular in plan and arranged for rotation relative to the frame about a rotational axis perpendicular to the planar upper surface of the light transmitting surface screen.

Optionally, the heat sink is adapted to be embedded in a substrate below the frame; and the ground plate is adapted to be embedded in substrate below the frame.

The solar paving module may further comprise a driver for driving rotation of the tracking disc, the driver comprising a vertical drive shaft rotationally driven by an external actuator. The external actuator may comprise one or more drive rods or drive cables offset from the rotational axis of the tracking disc and connected by a crank to the vertical driveshaft. Each group of drive rods or drive cables may be movable by a central motor or central geared motor unit

According to a second aspect of the present invention there is provided a solar paving module comprising:
a frame,
a power generating element comprising at least one photovoltaic element supported in the frame,
a light transmitting surface screen covering the electrical power generating element and having a planar upper surface, and
an electrical connector connected electrically to the power generating element,
wherein the at least one photovoltaic element comprises at least one substantially planar solar cell oriented in a tilted plane which is tilted relative to the planar upper surface of the light transmitting surface screen.

A paving module is a module which can be located on the ground as a load bearing paver. It is capable of bearing the loads associated with the environment in which it is used, for example pedestrian or vehicle loading, without damage.

Instead of the photovoltaic element comprising at least one substantially planar solar cell oriented in a tilted plane which is tilted relative to the planar upper surface of the light transmitting surface screen, the photovoltaic element itself may be oriented such that it is tilted relative to the planar upper surface of the light transmitting surface screen.

The tilted plane may be tilted at angle of between 5 and 50 degrees, optionally between 15 and 45 degrees, relative to the planar upper surface of the light transmitting surface screen. The actual angle of tilt may be selected depending upon where the module is to be installed, so that the angle of tilt is optimised depending on the local position of the sun and the variation in position of the sun between summer and winter. If the module is to be installed in at a location having a latitude of between 20 and 30 degrees, the angle of tilt may be between 15 and 25 degrees, or about 20 degrees. In locations nearer the equator the tilt angle is smaller than at locations further from the equator. Larger and smaller tilts are possible, outside the above range, to suit local conditions.

The electrical power generating element may be encapsulated by the surface screen. The electrical power generating element may be a monofacial photovoltaic element, and the encapsulation may be on the upper side of the photovoltaic element only. The monofacial photovoltaic element may rest on a heat conducting support surface. The photovoltaic element may be a bifacial photovoltaic element, and the encapsulation may be on both the upper and lower sides of the photovoltaic element. The portion of the surface screen below the photovoltaic element may rest on a support surface, which may be heat conducting. The electrical power generating element may comprise one or more elements of monocrystalline, polycrystalline, amorphous, single-junction, multi-junction, silicon-based, cadmium telluride based, quantum dots-based, and concentrated photovoltaic elements.

The solar paving module may comprise a plurality of photovoltaic elements arranged parallel to each other, each photovoltaic element comprising at least one substantially planar solar cell oriented in a tilted plane which is tilted relative to the planar upper surface of the light transmitting surface screen, or each photovoltaic element being oriented such that it is tilted relative to the planar upper surface of the light transmitting surface screen.

The solar paving module may comprise a corrugated support sheet comprising a plurality of parallel support surfaces, each support surface having at least one photovoltaic element of the power generating element supported thereon. The support sheet may be of a thermally conductive material, optionally of a metal such as steel, aluminium or an alloy thereof.

The solar paving module may comprise a heat sink in thermal connectivity with the power generating element. The heat sink may comprise a heat sink plate and a heat sink anchor connected to the heat sink plate.

The heat sink anchor may comprise a plurality of heat dissipating fins, which may be arranged to extend radially outwardly from the heat sink anchor.

The corrugated support sheet may comprise the heat sink plate. Alternatively the heat sink plate may comprise a substantially planar base plate and a plurality of photovoltaic element supports connected to the substantially planar base plate, wherein the power generating element is supported on the photovoltaic element supports.

Alternatively the heat sink anchor may comprise one or more ground plates connected to the heat sink plate. The heat sink plate may be substantially parallel to the planar upper surface of the light transmitting surface screen and the one or more ground plates may extend substantially perpendicular to the heat sink plate. The heat sink plate and the one or more ground plates may be a single folded plate, which may be metallic or non-metallic, for example steel, aluminium or an alloy thereof.

Alternatively the heat sink plate and/or the one or more ground plates may comprise one or more metallic mesh panels. The heat sink plate which is substantially parallel to the planar upper surface may comprise a metallic mesh panel and the one or more ground plates which extend substantially perpendicular to the heat sink plate may each comprise an upper metallic mesh panel portion and a lower plate portion.

The frame may comprise a recess, in which the power generating element and surface screen are located, and a border surrounding the recess, wherein the upper surface of the border is substantially coplanar with the upper surface of the surface screen.

The frame may be polygonal in plan, for example a regular hexagon, a rectangle or a square. The frame may be irregular in plan, for example having a perimeter comprising a plurality of straight sides and a plurality of curved sides.

The frame may be of concrete, other cementitious material, plastic, recycled plastic or a mixture thereof. The frame may be reinforced with steel or glass reinforced plastic or other reinforcing material.

The surface screen may be circular or polygonal in plan, for example a regular hexagon, a rectangle or a square. The surface screen may be irregular in plan, for example having a perimeter comprising a plurality of straight sides and a plurality of curved sides.

The electrical connector may be adapted to form an electrical connection with an electrical connector of a second like solar paving module when the solar paving module is placed next to the second like solar paving module.

The surface screen and the power generating element may be arranged for rotation together relative to the frame. The surface screen and the power generating element may together form a tracking disc which is circular in plan and arranged for rotation about a rotational axis perpendicular to the planar upper surface of the light transmitting surface screen. The tracking disc may also include the corrugated support sheet and/or the heat sink plate.

The solar paving module may comprise a driver for driving rotation of the tracking disc. The driver may comprise an electrical motor in the solar paving module.

Alternatively the driver may comprise a vertical drive shaft rotationally driven by an external actuator.

In one embodiment the vertical drive shaft may comprise a shaft of the heat sink anchor. The shaft of the heat sink anchor may extend along the rotational axis of the tracking disc. The shaft of the heat sink anchor may be rotationally fixed to the tracking disc. The shaft of the heat sink anchor may be arranged for rotation in a bearing unit. The bearing unit may be connected to a plurality of heat dissipating fins of the heat sink anchor.

The external actuator may comprise a drive rod offset from the rotational axis of the tracking disc and connected by a crank to the shaft of the heat sink anchor. The drive rod may connect a plurality of cranks of a plurality of solar paving modules. The drive rod may be driven by an electric motor.

Alternatively the external actuator may comprise a pair of drive cables, each offset on opposite sides of the rotational axis of the tracking disc and each connected by a crank to the shaft of the heat sink anchor. The pair of drive cables may connect a plurality of cranks of a plurality of solar paving modules. The pair of drive cables may be driven by an electric motor in opposite directions. The motor may be geared or gearless.

According to a third aspect of the present invention there is provided a paving construction comprising a plurality of solar paving modules according to the first or second aspect, the electrical connector of each of the plurality of solar paving modules being connected to the electrical connector of another of the plurality of solar paving modules.

Each of the plurality of solar paving modules may comprise a plurality of electrical connectors, each electrical connector being connected to the electrical connector of another of the plurality of solar paving modules and/or an electrical storage means and/or an electrical or electronic interface.

According to a fourth aspect of the present invention there is provided a paving construction comprising a plurality of solar paving modules according to the second aspect of the invention arranged in a line, wherein the surface screen and the power generating element of each solar paving module together form a tracking disc which is circular in plan and arranged for rotation about a rotational axis perpendicular to the planar upper surface of the light transmitting surface screen, wherein each solar paving module comprises a vertical drive shaft rotationally driven by an external actuator for driving rotation of the tracking disc.

The electrical connector of each of the plurality of solar paving modules may be connected to the electrical connector of another of the plurality of solar paving modules.

The external actuator may comprise a drive rod offset from the rotational axes of each of the tracking discs and connected by a respective crank to each vertical drive shaft. The drive rod may be driven by an electric motor, which may be geared or gearless.

Alternatively the external actuator may comprise a pair of drive cables, each offset on opposite sides of the rotational axes of each of the tracking discs and connected by a respective crank to each vertical drive shaft. The pair of drive cables rod may be driven by an electric motor in opposite directions. The motor may be geared or gearless.

According to a fifth aspect of the present invention, there is provided a railway comprising:
two parallel rails;
at least one paving module in accordance with the first aspect located between the rails; and
at least one fastening member arranged to attach the at least one paving module to at least one of the rails.

The at least one fastening member may be arranged to attach the one or more ground plates to at least one of the rails.

### BRIEF DESCRIPTION OF THE DRAWINGS

The invention will now be described, by way of example only, with reference to the drawings in which:

FIG. 1 shows a solar paving module according to a first embodiment of the invention;

FIG. 2 shows the base plate and heat sink of the solar paving module of FIG. 1;

FIG. 3 is a cross section through the solar paving module of FIG. 1;

FIG. 4 is a partial cross-sectional view through a solar paving module according to a second embodiment of the invention;

FIG. 5 is a cross sectional view through the solar paving module of FIG. 4;

FIG. 6 shows a solar paving module according to a third embodiment of the invention;

FIG. 7 shows an array of solar paving modules according to FIG. 6;

FIG. 8 shows a solar paving module according to a fourth embodiment of the invention;

FIG. 9 shows an array of solar paving modules according to the embodiment of FIG. 8;

FIGS. 10a and 10b show the frame of a solar paving module according to a fifth embodiment of the invention;

FIG. 11 shows an array of solar paving modules according to a sixth embodiment of the invention;

FIGS. 12a, 12b and 12c show a solar paving module according to a seventh embodiment of the invention;

FIG. 13 shows an array of solar paving modules according to an eighth embodiment of the invention;

FIG. 14a to FIG. 14m show a solar paving module according to a ninth embodiment of the invention;

FIG. 15 shows part of a solar paving module which may be incorporated in the embodiment of FIG. 14a to FIG. 14m;

FIGS. 16a to 16e show an array of solar paving modules according to the ninth embodiment of the invention;

and

FIG. 17 shows a fastener suitable for use with paving modules of the ninth embodiment of the invention.

### DETAILED DESCRIPTION OF SPECIFIC EMBODIMENTS

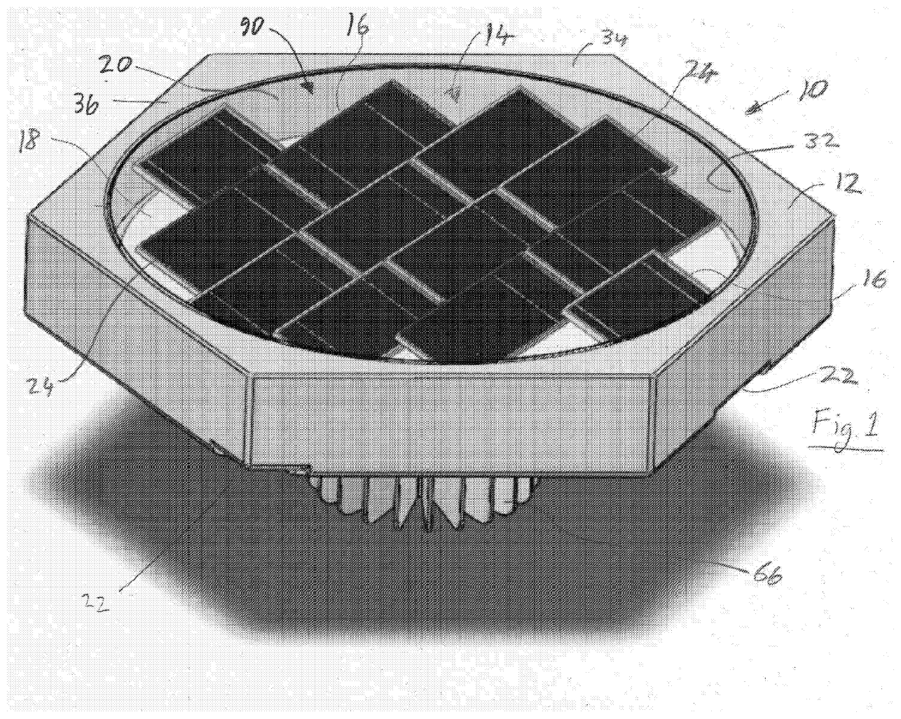

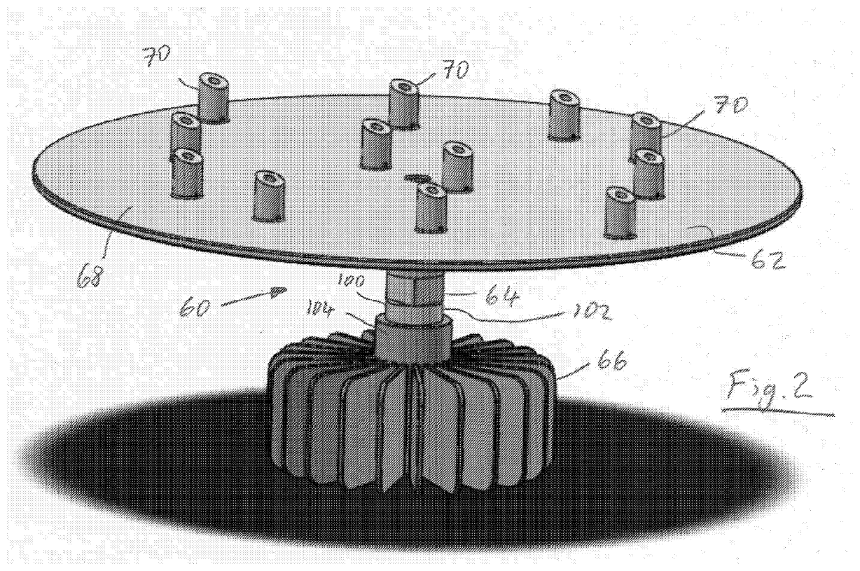

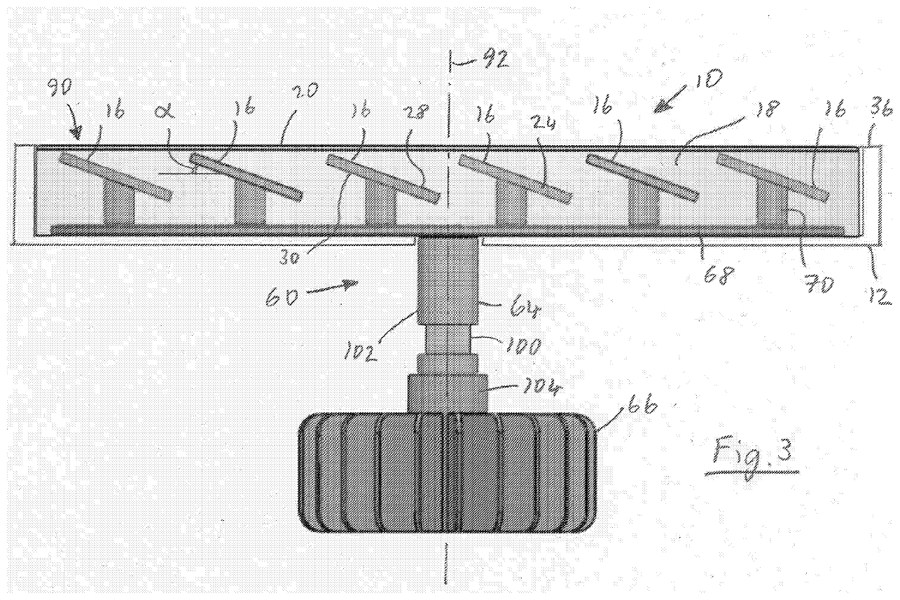

Referring to FIGS. 1 to 3, there is shown a solar paving module 10 comprising a hexagonal frame 12. The frame 12 can be formed of any suitable material, such as concrete, other cementitious material, plastic, glass reinforced plastic, recycled plastic or a mixture of these materials. The frame 12 has a recess 32 in which is located a tracking disc 90 comprising a solar power generating element 14 covered by a light transmitting surface screen 18. The power generating element 14 comprises an array of photovoltaic elements 16, with each photovoltaic element comprising one or more substantially planer solar cells 24, or curved cells arranged in a substantially planar array. The solar cells 24 are arranged at a tilt angle to the planer upper surface of the light transmitting surface screen 18. The tilt angle α is typically about 20 degrees, but is selected according to the location in which the solar paving module 10 is to be installed, so that the collected solar energy is maximised. In use the solar paving module 10 is oriented so that the solar cells 24 tilt towards the south, if installed in the northern hemisphere, and towards the north, if installed in the southern hemisphere.

Each photovoltaic element 16 is supported on a photovoltaic element support 70, which is fixed to a substantially planer base plate 68. The plate 68 and support 70 are of a heat conducting material, optionally a metal such as steel, aluminium or an alloy thereof, and conduct heat away from the photovoltaic elements 16.

There is a gap between the tracking disc 90 and the border 34 of the frame 12 which surrounds the recess 32. The upper surface 36 of the border 34 is co-planer with the upper surface 20 of the light transmitting surface screen 18 of the tracking disc 90.

The base plate 68 is fixed to a heat sink anchor 64 which in use extends into the ground on which the solar paving module 10 is installed. In the embodiment of FIGS. 1 to 3 the heat sink anchor 64 includes a shaft 102 which serves as a vertical drive shaft 100 which causes the tracking disc 90 to rotate. The shaft 102 can be solid or hollow, and can be used to carry wiring therein. The speed of rotation is such that the solar cells track the sun as it passes across the sky, therefore the rotational speed is very low. The vertical drive shaft 100 is held in a bearing unit 104 which is fixed in the ground. The bearing unit 104 has attached to it a number of heat dissipating fins 66, which form part of the heat sink 60, and help to carry heat away from the solar cells 24 into the ground, thereby increasing the efficiency of the solar cells.

When installed, the solar paving module 10 is supported in the ground both by the lower end of the heat sink 60, and by the underside of the frame 12. If required, a spacing sleeve can be provided around the vertical drive shaft 100, so that the vertical dive shaft is not in direct contact with the surrounding ground.

In an alternative embodiment, the bearing unit 104 is omitted and the fins 66 are free to rotate with the drive shaft 100 in a cavity under the paving module.

The rotation of the tracking disc 90 can be controlled by an electric motor within the solar paving module (not shown) or by an external actuator, which is described below. The rotation of the tracking disc 90 provides variable orientation of the tilted rows of photovoltaic elements 16 towards the sun throughout the day. In practice this rotation can be step-wise and is extremely slow. For example, the tracking disc 90 may rotate through about 90° to 100° over a period of 6 hours, which may be the period of time during which the sun is sufficiently high in the sky for useful power generation. This requires a rate of rotation of the order of only 1 degree every 4 minutes or so. In practice therefore a step change of 1° can be provided every 3 to 4 minutes.

During the night, the tracking disc 90 can be rotated step-wise (or at any predefined rotational speed) in the reverse direction to return to the initial position, ready for next day.

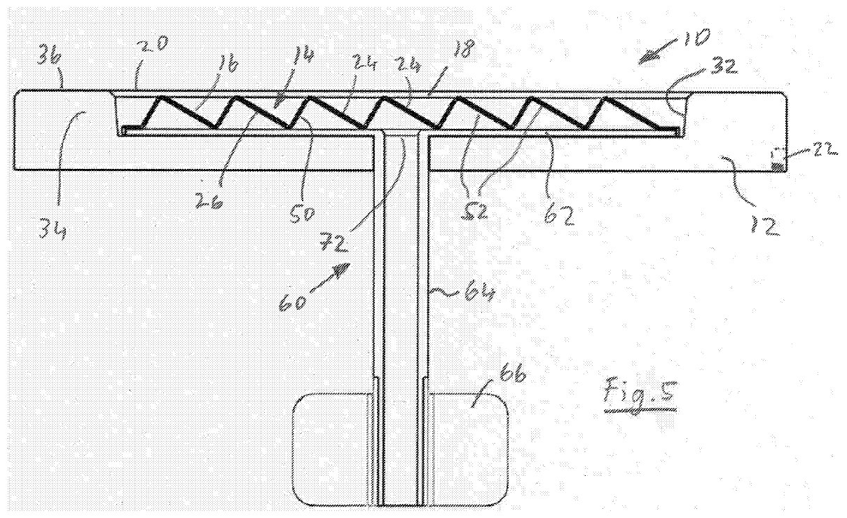

A simple, rigid and long-life mechanism utilizing high torque transmission ratios can be powered by one or more central low-power controlled motors, as described below with reference to FIGS. 6 to 9.

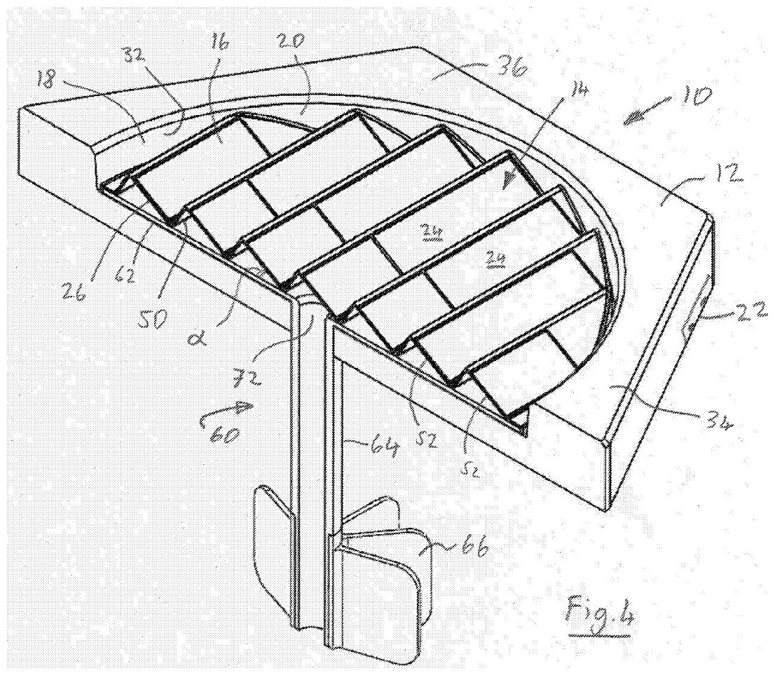

A solar paving module 10 according to a second embodiment is described with reference to FIGS. 4 and 5. In this embodiment the power generating element 14 does not rotate relative to the frame, and is held in a fixed position, so that the solar cells 24 face in the optimum direction, which may for example be generally south, if installed in the northern hemisphere, or north if installed in the southern hemisphere. In this embodiment the heat sink anchor 64 is connected to a heat sink plate 62 which supports a corrugated support sheet 50. The corrugated support sheet 50 comprises multiple parallel support surfaces, each inclined at a tilt angle α with respect to the planer upper surface of the light transmitting surface screen 18. Unlike the embodiment of FIGS. 1 to 3 where the tracking disc 90 must be made separately, and then mounted in the frame 12, in the embodiment of FIGS. 4 to 5 the corrugated support sheet 50 and heat sink plate 62 are placed in the recess 32 of the frame 12, and the light transmitting surface screen 18 can be formed by pouring an epoxy or polymer based resin or similar onto the photovoltaic elements 16 to fill the recess. In this way the photovoltaic element 16 are encapsulated in the surface screen 18. The surface screen 18 is finished so that the upper surface 20 of the surface screen 18 is co-planer with the upper surface 36 of the border 34 of the frame 32.

A number of electrical connectors 22 are provided around the edge of the solar paving module 10, to permit adjacent solar paving modules 10 to be electrically connected together.

Alternatively, the heat sink plate 62 has an aperture 72 in the middle through which connecting wires (not shown) are used to electrically connect the photovoltaic cells 16 to the terminals of the electrical connectors 22. The connecting wires can be routed down the hollow shaft 64.

The heat sink 60 comprises a heat sink plate 62, which in this case is a flat horizontal plate 62 enclosed inside the surface screen 18. The plate 62 does not necessarily need to be of the same shape as the screen 18, and can be of round, square, polygonal or irregular shape. The plate 62 rests on the heat sink anchor 64, which in this embodiment is a vertical hollow shaft. The heat dissipating fins 66 are optionally connected to the heat sink anchor 64 below ground level. As in the embodiment of FIGS. 1 to 3, the shaft of the anchor 64 may be formed of two or more interlinked sections. At least part of the shaft 64 is buried in the ground for firm mounting and heat dissipation.

The heat dissipating fins 66 can be of any suitable shape to provide a large surface area in direct contact with the ground for better heat dissipation. Instead of the generally rectangular shape illustrated in FIG. 4, the fins 66 could comprise a single vertical hollow cylinder fixed to the shaft or a number of concentric vertical cylinders fixed to the shaft.

In another alternative the heat sink plate 62 could extend beyond the surface screen 18 into the border 34 of the frame 12, surrounding the recess 32, so that the heat sink plate 60 is at least partially embedded in the frame. It can be embedded during the moulding of the frame 12. For example, if the screen 18 is round, a square plate 62 of side length similar to or close to the screen diameter will increase the mechanical strength of the combined structure of the screen 18 and frame 12.

The photovoltaic elements 16 are arranged in parallel rows and each element rests separately on a metal holder, in this case a corrugated support sheet 50 integral with the heat sink plate 62. As in the embodiment of FIGS. 1 to 3 or any other rotating screen embodiment, if required the planar plate 62 can be omitted and the corrugated support sheet 50 can form the heat sink plate and be connected directly to the heat sink anchor 64.

In case of bifacial photovoltaic elements 16, the corrugated support sheet 50 or other holders must be made of a transparent material; for instance, a polymer-based holder, or a hollow metallic frame that exposes the back side of the photovoltaic elements 16 to reflected or diffused sunlight. The photovoltaic elements 16 are tilted at an angle α relative to the planar upper surface of the surface screen 20. The exact tilt angle α is decided in the manufacturing phase based on the installation location of the system and the corresponding optimal solar tilt angle. Once set to the correct angle during manufacturing, the photovoltaic elements cannot change their tilt angle later being surrounded by the solid encapsulation material of the surface screen 18.

In an alternative method of mounting the photovoltaic elements 16, which is applicable to the embodiment of FIGS. 1 to 3 and to the embodiment of FIGS. 4 and 5, each row of photovoltaic elements 16 can rest on a single rectangular metal sheet extending from one side of the heat sink plate 62 to the other, the single sheet being tilted to the desired tilt angle and firmly fixed to the plate at both ends of each row. In the case of bifacial photovoltaic cells, the tilted rectangular sheets are made of transparent material, for example polymer-based sheets, or of a partially transparent frame that exposes the back side of the photovoltaic elements 16 to reflected or diffused sunlight.

In the case of monofacial photovoltaic elements, the elements 16 rest directly on the corrugated metal support sheet 50 or the separate rectangular metal sheets, which are set at the required tilt angle.

FIGS. 6 and 7 show an embodiment which is similar to that of FIGS. 4 and 5, in that it uses a corrugated support sheet 50 to provide parallel support surfaces 52 for the solar cells 24, but in this embodiment the power generating element 14 and surface screen 18 are formed as a rotatable tracking disc 90, together with the heat sink plate 62, so that the tracking disc 90 can rotate about the rotational axis 92 perpendicular to the planar upper surface of the surface screen 20, and thereby maximise the collected sunlight at different times of the day. Components which are the same in FIGS. 6 and 7 as in FIGS. 1 to 3 or FIGS. 4 and 5 are shown with the same reference number, and are not described further. It is to be understood that the corrugated support sheet 50 can be used in tracking and non-tracking embodiments.

In the embodiment of FIGS. 6 and 7 the drive means for the vertical drive shaft 100 is a crank 122 which is fixably connected to the shaft 102 of the heat sink anchor 64. As can be seen in FIG. 7, a pair of drive cables 120 connect the cable connectors 124 at the ends of each crank 122 of a series of solar paving modules 10. The cables 120 are driven by one or more electric motors 126, of which one is shown in FIG. 7. It is to be understood that the connection to the motor 126 illustrated in FIG. 7 is purely schematic, and any suitable connection can be used. Because the speed is so low and the distance travelled so small, only a small force is required to rotate a large number of tracking discs 90, considering the required high gear ratio in a geared mechanism. The drive cables 120 can be sheathed, so that there is no friction between them and the surrounding ground, while a void may be formed around the crank 122 at each solar paving module, so that the crank is free to rotate under the action of the drive cables 120. Any suitable void former, for example a plastic box or an inverted channel member, can be used to form the void.

The motor 126 is typically an electric geared motor, i.e. a motor-gearbox assembly with a high gear ratio, with a horizontal pulley connected to its output shaft. In the embodiment of FIGS. 6 and 7 the pulley has two cables, which may be self-lubricated steel wire ropes, connected to its ends. The cables are then connected to each shaft by a fastened pivot 124 to a crank 122 in the form of a horizontal rocker link. When the motor 126 turns in small steps in a specific direction, the cable 120 under tension turns the tracking discs 90 in the same direction, and when the motor 126 reverses its direction, the other cable 120 becomes under tension and turns the tracking discs 90 in the opposite direction. The lengths of the cranks or rocker links, the cable diameter and the motor and/or gearbox sizes are selected appropriately according to the overall number of solar paving modules 10 to be driven. The whole actuation mechanism may be enclosed within one or more solid channels to keep the moving parts away from the surrounding soil to allow ease of motion and maintenance.

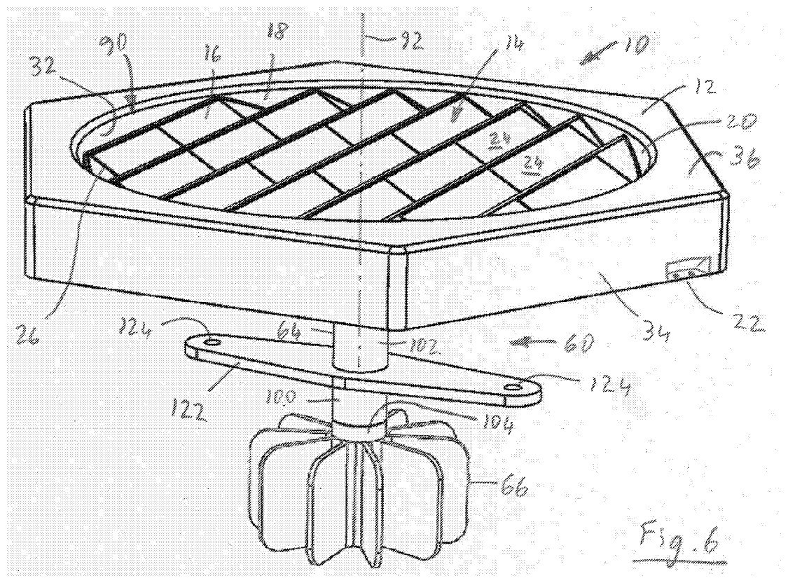

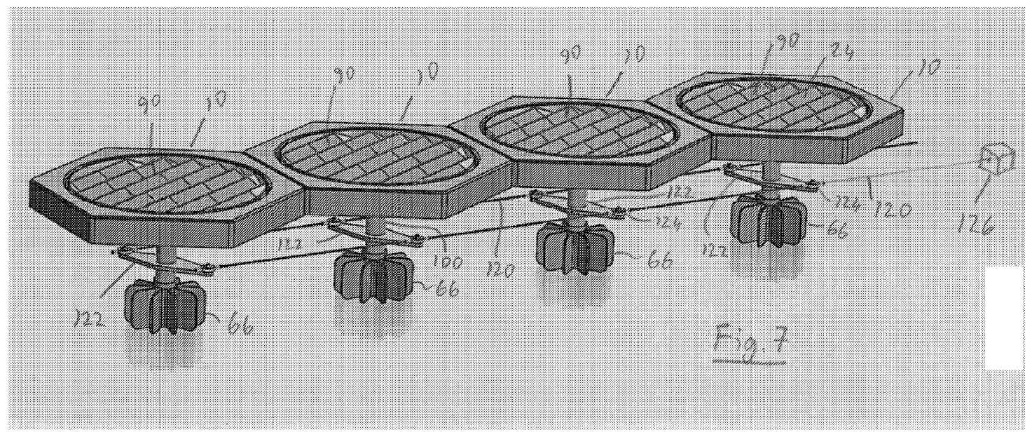

FIGS. 8 and 9 show a further embodiment of a solar paving module 10 according to the invention. The module 10 of FIGS. 8 and 9 is similar to that shown in FIGS. 6 and 7, except that instead of drive cables 120, a drive rod 106 is used to drive the crank 108. As can be seem in FIG. 9 the array of solar paving modules 10 can be driven by a number of drive rods 106, and the rods can be interlinked at one end, so that they are all driven by a single geared or gearless electric motor 110, or each rod can be driven separately by a geared or gearless electric motor 110, of which one is indicated in FIG. 9. The rods can be sheathed to reduce friction between the rod and the ground, or the rods can be installed in troughs underneath the frames 12 of the solar paving modules 10.

The drive rods 106 and cranks 108 form a four-bar linkage mechanism. The motor 110 is configured to transmit the rotating motion to the tracking discs 90 simultaneously to achieve the tracking rotation. The drive rods 106 and cranks 108 can serve as additional heat dissipation means.

If a geared motor is used, the gearbox transmission ratio is selected to be high enough such that the produced torque is sufficient to rotate the tracking disc 90 in each connected paving module 10 for the required small angular step, even if there is a vertical loading on the tracking disc 90 due to pedestrians or other traffic, and to overcome any friction between the moving parts and the surrounding soil.

Instead of the fins 66 being static and the shaft 102 of the heat sink anchor being supported in a bearing unit 104, the fins 66 may be rigidly connected to the shaft 102, and may rotate with the shaft. In this case the fins 66 are of a shape that can rotate smoothly with minimum friction against soil, for example the fins may be cylindrical shaped fins. Alternatively, the fins 66 can be allowed to rotate inside a cavity of a slightly bigger diameter than the fin diameter. The cavity may be formed by a spacing sleeve.

If bifacial photovoltaic elements 16 are used, the side walls and/or bottom section of the surface screen 18 below the level of the photovoltaic elements 16 can be provided with embedded curved or flat reflector elements (not shown) to direct as much ground-reflected and diffuse light as possible to the bottom surface of the bifacial photovoltaic elements 16.

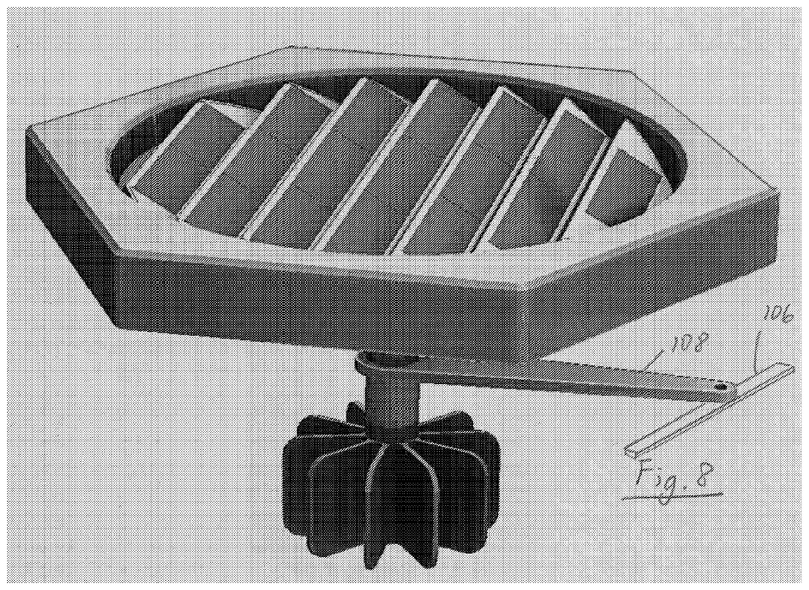

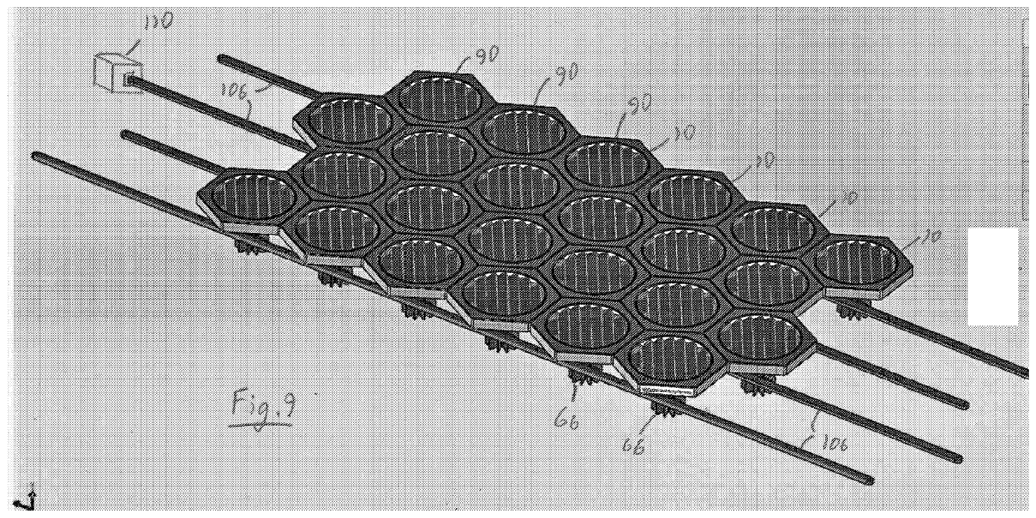

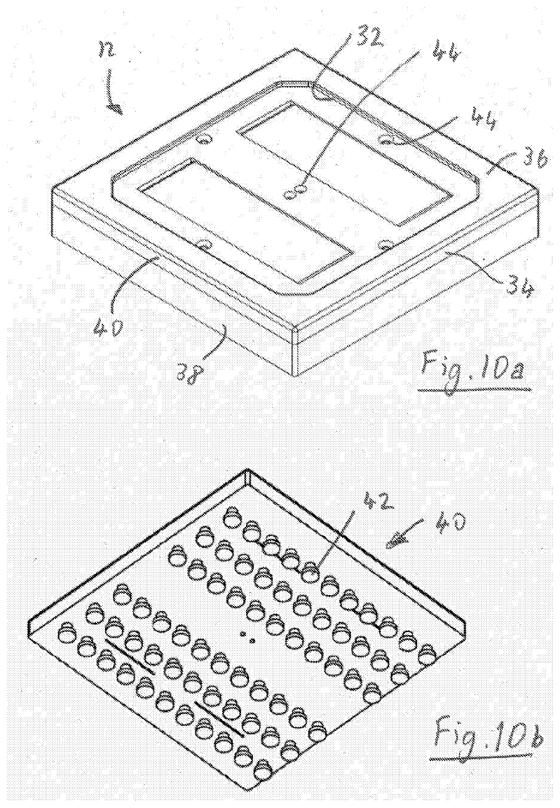

FIGS. 10a and 10b show a composite frame 12. Although this frame is shown as a rectangular frame, the same method of construction can be used for any frames including the hexagonal frames shown in FIGS. 1 to 9. The frame 12 comprises a lower portion 38 formed of concrete or mortar or other cementitious product, and an upper portion formed of plastic, optionally moulded recycled plastic. The upper portion 40 has a number of studs 42 on the bottom, so that it can be placed in a mould in which the lower portion 38 is formed, such that the concrete or mortar hardens around the studs 42. The upper portion 40 of plastic has a number of apertures 44 for the passage of electrical cables which take the generated power from the power generating elements 14 to adjacent solar paving modules and from there to an electrical energy store.

FIG. 11 shows a number of frames 12 electrically interconnected. In the illustrated example each frame 12 has two connectors 22 on each side, a male connector 22a and a female connector 22b. The male connector 22a includes two contacts 23a which after connection engage with two contacts 23b on the female connector 22b. As will be appreciated, the internal wiring (not shown) of each frame 12 can be adapted to permit each connector 22 to provide a parallel or series connection of the solar power generating elements 14 of adjacent solar paving modules 10 as required.

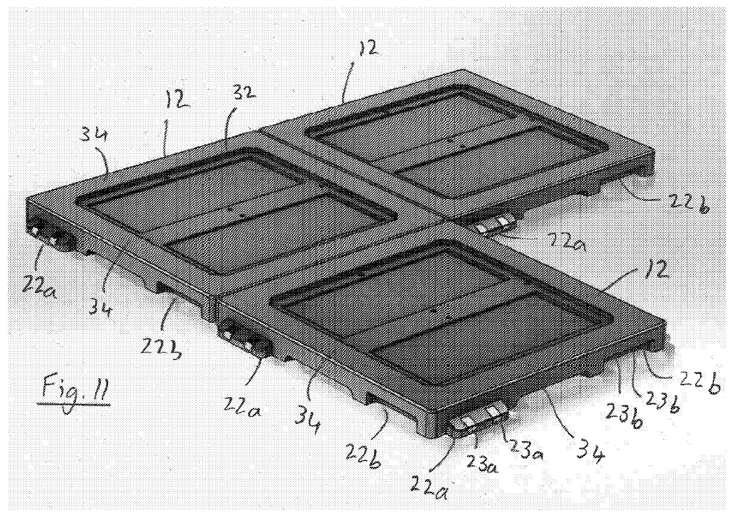

FIGS. 12 and 12b show a further embodiment of a solar paving module 10 according to the invention. The module 10 of FIGS. 12a and 12b has four monofacial photovoltaic elements 16, although any suitable number may be provided. Each element 16 is supported on a heat sink plate 62 of a heat sink 60 having a heat conducting support surface 26. Each heat sink 60 is formed as a folded metallic plate, for example of steel or aluminium or alloy thereof. Each heat sink 60 includes two ground plates 80 connected to the heat sink plate 62, which in use extend into the ground beneath the paving module 10, through apertures in the frame 12. The heat sink 60 serves to lower the temperature of the photovoltaic elements 16 by carrying heat from the photovoltaic elements 16 down through the ground plates 80 to the ground, thereby increasing the efficiency of the photovoltaic elements 16.

FIG. 12c shows an alternative heat sink 60A construction which can replace the folded plate construction shown in FIGS. 12a and 12b. In this embodiment 82 each photovoltaic elements 16 is supported on a heat sink plate 82 of the heat sink 60A which comprises a metal mesh panel 82, such as a steel reinforcing mesh used in reinforced concrete. The heat sink is folded so that each ground plate 80 comprises an upper portion 84 formed of a folded portion of the mesh panel, and a lower portion 86 formed of a metal plate, for example of steel or aluminium or alloy thereof. The mesh panel 82 allows improved encapsulation by the light transmitting surface screen, which can flow at least partially beneath the photovoltaic elements 16 and bond with the mesh panel. As depicted, each of the ground plates 80 extends beyond the frame 12. Specifically, the ground plates 80 extend beyond a base of the frame 12.

In the embodiment of FIGS. 12a to 12c, the photovoltaic elements 16 rest horizontally with zero tilt angle. As an alternative to the C-shaped metal heat sink elements 60 which have the heat sink plate 62 embedded horizontally in the frame, and to further reduce stress on the frame structure due to thermal expansion, the heat sink 60 can comprise one or more pairs of opposed L-shaped metal sections embedded in the frame such that the longer side of each L-shaped element lies horizontally in the frame and the shorter side of the L shape extends vertically downwards. Both L-shaped elements are placed in the frame with a short distance between them so as to form an equivalent downward-pointing C-shaped element.

If bifacial photovoltaic elements 16 are used, they are embedded in the surface screen 18 such that there is a transparent layer below the photovoltaic elements 16 as well as on top. The walls and/or bottom section of the surface screen 18 below the level of the photovoltaic elements 16 can optionally be provided with embedded curved or flat reflector element(s) to direct as much incident light as possible to the bottom surface of the bifacial photovoltaic elements 16. Alternatively the bifacial photovoltaic elements 16 can be utilized in a 2-layer surface screen structure, which includes, from top to bottom, the transparent surface screen 18, the bifacial photovoltaic elements 16, another transparent polymer-based layer, and the frame 12.

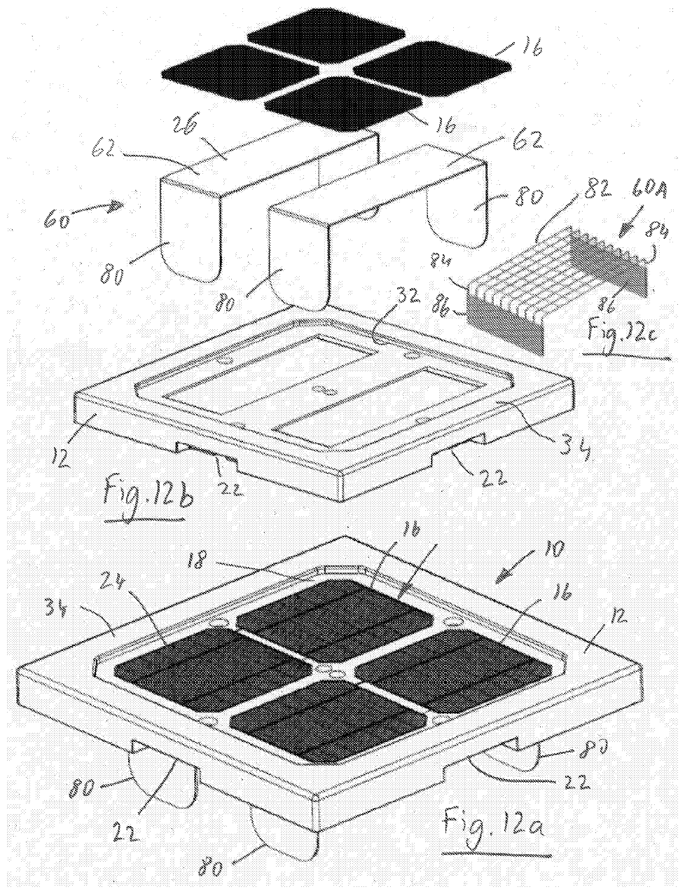

Referring to FIG. 13 there is shown schematically how a number of paving modules 10 can be installed and connected for rotation of the tracking discs 90 in a paving construction 140. The geared or gearless motor 126 drives two primary drive cables 130, which drive the rotation of a series of drive units 132. Each drive unit 132, when it rotates, drives two secondary drive cables 120, which together drive the cranks 122 of the drive shafts 100, as described above with reference to FIG. 7. In the example of FIG. 13 each drive shaft 100, which also serves as the shaft 102 of the heat sink anchor 64, has at least two interlinked sections. The lower interlinked section 102A can be seen projecting up from the fins 66 of the heat sink. The upper interlinked section (not shown) projects beneath the tracking disc 90 of the paving module 10, and engages with the lower interlinked section 102A when the paving module 10 is lowered onto the ground. A support channel 134A sits on the ground and encloses the two primary drive cables 130 and the series of drive units 132. A cover (not shown) may cover the support channel 134A. An array of ground support beams 134B extends parallel to the support channel 134A. These also rest on the ground. Supported by the array of ground support beams 134B is an array of inverted channels 136, which each have a number of apertures 138 therein. The lower interlinked sections 102A extend through the apertures, to engage with the upper interlinked sections and the tracking discs 90. Hence operation of the motor 126 causes the same rotation of each tracking disc 90. Although only one paving module 10 is shown in FIG. 13, it will be appreciated that a paving module 90 can be installed at the location of each lower interlinked sections 102A. Backfill material, which may extend around the inverted channels and beneath the paving modules 90, is omitted for clarity. Although the embodiment of FIG. 13 uses drive cables 120, 130, it will be appreciated that each pair of drive cables 120, 130 can be replaced by one or two drive rods 106, as shown in FIG. 9, such that the tracking discs are driven in the manner illustrated in FIGS. 8 and 9.

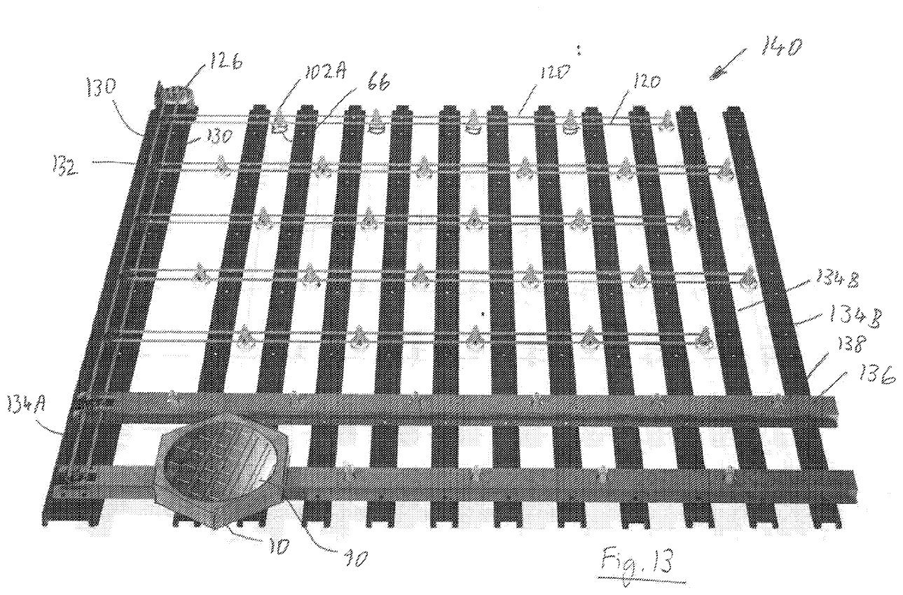

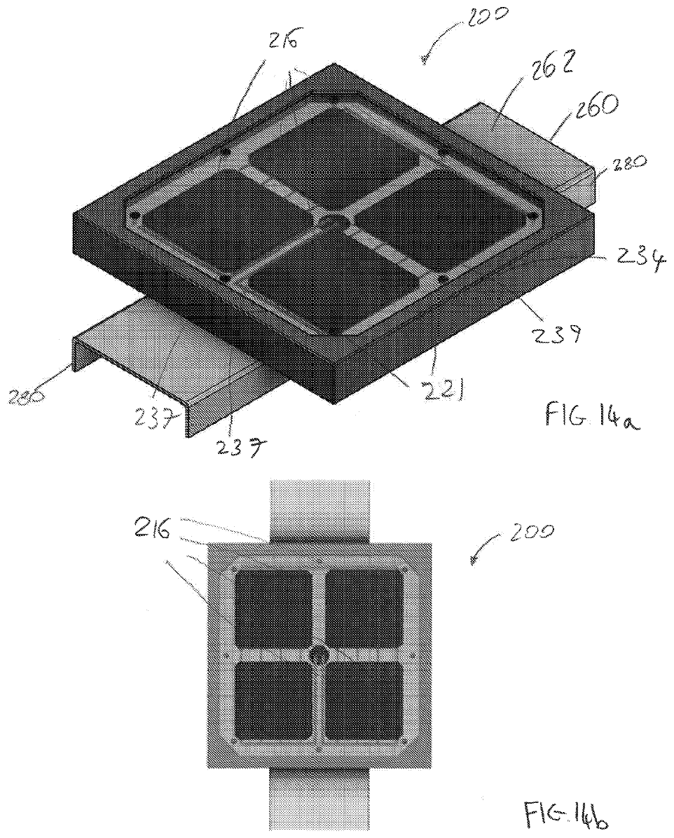

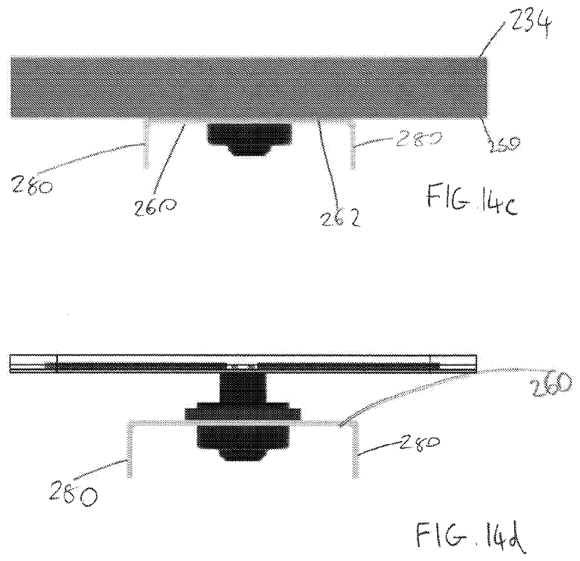

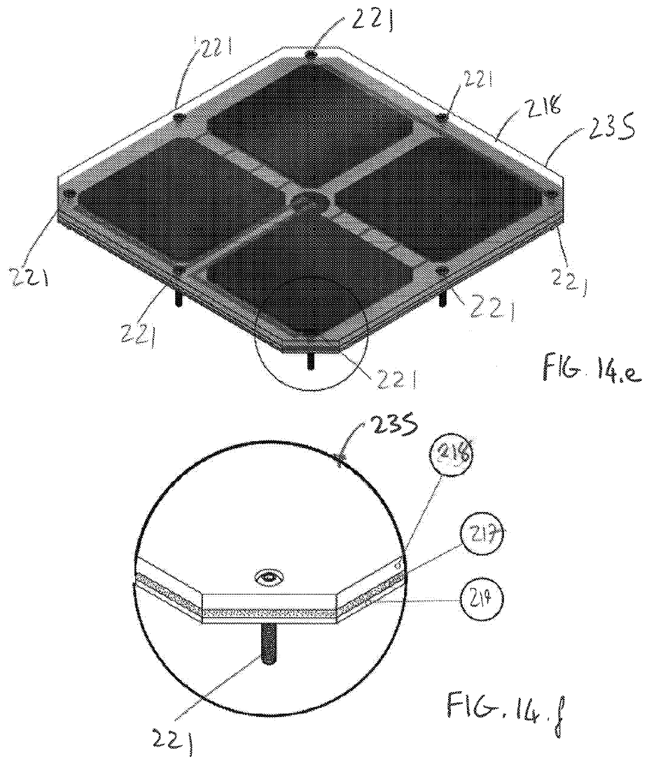

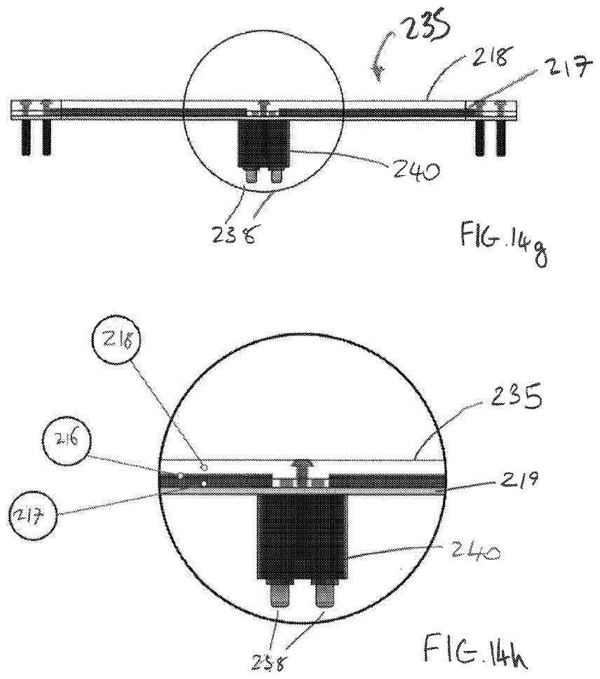

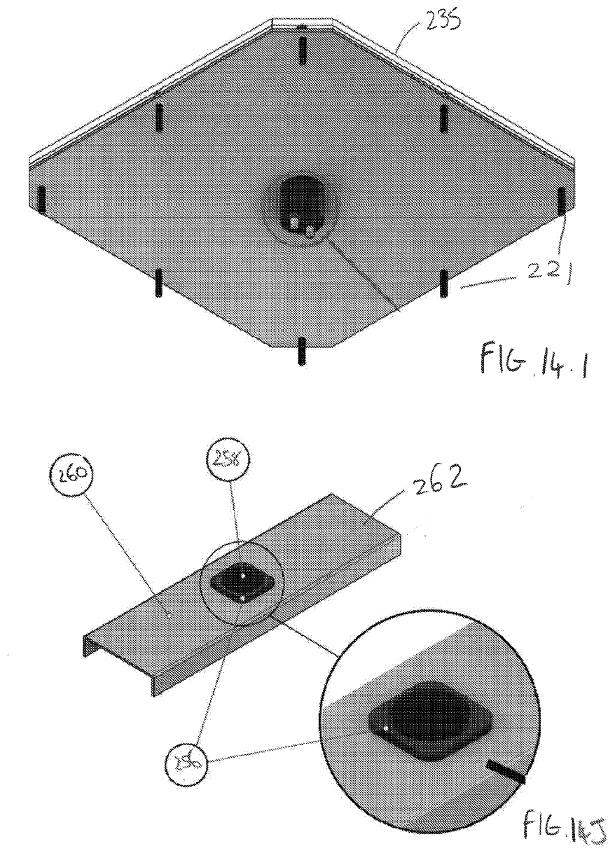

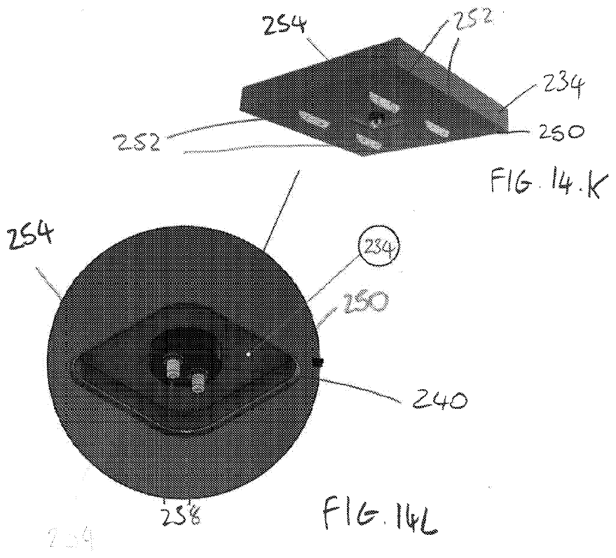

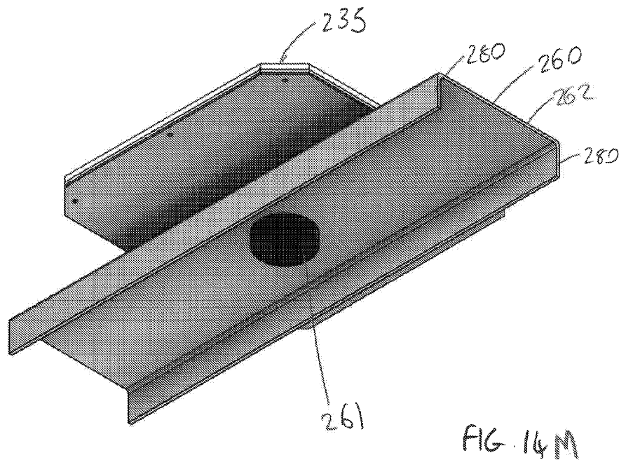

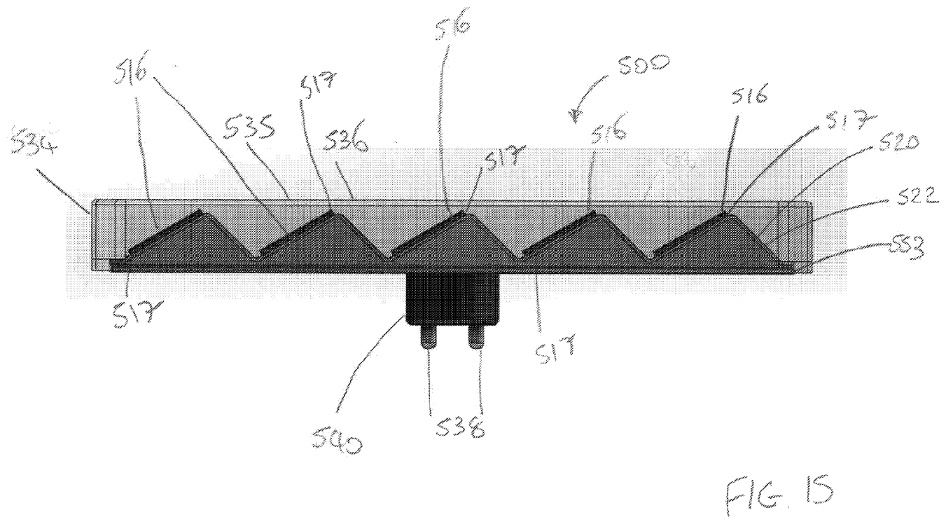

Referring now to FIGS. 14a to 14m, there is shown a solar paving module 200 according to a ninth embodiment of the invention. Referring to FIG. 14a specifically, the module 200 has four monofacial photovoltaic elements 216, although any suitable number may be provided. Each element 216 is supported on a heat sink plate 262 of a heat sink 260, which forms a heat sink anchor. The heat sink 260 is optionally formed of metal. Optionally, it may be formed of a folded metallic plate, for example it may be formed of steel or aluminium or an alloy thereof. Each heat sink 260 includes two ground plates 280 connected to the heat sink plate 262, which in use extend downwardly towards the ground beneath the paving module 200. The heat sink 260 serves to lower the temperature of the photovoltaic elements 216 by carrying heat from the photovoltaic elements 216 down through the ground plates 280 towards the ground, thereby increasing the efficiency of the photovoltaic elements 216. This further increases the efficiency, which is important when the module is located in an area that experiences very high temperatures such as the Middle East or Africa.

As shown in FIGS. 14.d and 14J, the heat sink 260 is optionally formed such that it is elongate and C-shaped in cross-section, thereby advantageously providing a channel for conduits and electrical cables to run in use when a number of modules 200 are arranged in a row with their heat sinks 260 connected end to end.

With reference to FIGS. 14g and 14h, the photovoltaic elements 216 are provided upon a support layer 217 of the module 200. The support layer 217 itself is provided upon a thermally conductive layer 219 of the module 200. The support layer 217 optionally comprises silicone and optionally additives that are provided to boost the thermal conductivity of the support layer. The support layer 217 may optionally comprise support sheets to electrically insulate the monofacial elements from the heat conduction layer 219. Suitable additives may be one or more of the following: carbon-based fillers such as graphite particles or graphite nanoplatelets (GNPs); and metallic or ceramic fillers such as aluminium oxide, aluminium nitride and silver. Optionally, the support layer 217 comprises silicone optionally with 50% to 60% of its content being composed of a hybrid filler comprising large-sized aluminium oxide and small-sized aluminium nitride particles. The thermally conductive layer 219 comprises metal, which provides additional strength to the module 200 (and optionally to the screen), but also acts to conduct heat down towards the heat sink 260. Optionally, the thermally conductive layer 219 is a metal plate. The support layer 217 may act as a shock absorber to avoid fracture of one or more of the photovoltaic elements in case of sudden force or overload applied to module.

The monofacial photovoltaic elements 216 are covered by a surface screen 218, which is housed within a frame 234 (as shown in FIG. 14a). The surface screen 218 is optionally formed from a clear polymer such as epoxy. Optionally, the surface screen 218, photovoltaic elements 216, support layer 217 and thermally conductive layer 219 are fused together as one piece 235, as shown in FIGS. 14e and 14h. This piece 235 is held within the frame 234 by a plurality of mechanical fixings 221 which extend downwards through the surface screen 218, and the support and thermally conductive layers 217, 219. Advantageously, these mechanical fixings 221 can be removed, meaning the piece 235 (as shown in FIGS. 14e) can be removed from the frame 234 and replaced as required. However, these mechanical fixings 221 are not essential because the piece 235 could be formed such that it may form a snap-fit connection with the frame 234 such that it can be detached from the frame by “unsnapping” it from the frame, and then reattached by “re-snapping” the piece into the frame. As depicted in FIG. 14a, the ground plates 280 extend beyond the frame 234. Specifically, the ground plates 280 extend beyond a base of the frame 234.

The support layer 217 optionally comprises a central supporting portion, which supports the photovoltaic elements, and a polymer surround portion which is formed from a polymer and surrounds the central supporting portion. The central supporting portion optionally comprises silicone. Each of the central supporting portion and polymer surround portion may comprise additives to improve the thermal conductivity of each portion. Suitable additives may be one or more of the following: carbon-based fillers such as graphite particles or graphite nanoplatelets (GNPs); and metallic or ceramic fillers such as aluminium oxide, aluminium nitride and silver. Optionally, the central supporting portion comprises silicone with 50% to 60% of its content being composed of a hybrid filler comprising large-sized aluminium oxide and small-sized aluminium nitride particles.

As shown in FIG. 14a, the monofacial photovoltaic elements 216 comprise electrical power conveying wires 237 which extend from each of the elements through a central aperture 239 in the module 200 (which extends through the piece 235) to two electrical terminals 238, which are shown in FIG. 14g. The electrical terminals 238 are provided within a hollow shaft 240. The hollow shaft 240 is optionally formed from a thermally conductive material and assists in conveying heat from the monofacial photovoltaic elements to the heat sink 260. As best shown in FIG. 14h, the hollow shaft 240 depends from the thermally conductive layer 219.

The frame 234 may be formed of any suitable material, such as concrete, other cementitious material, plastic, glass, polyurethane, fiberglass or reinforced plastic. As shown in FIGS. 14c and 14k, the frame 234 optionally comprises a foundation plate 250 which is in contact with the heat sink 260. However, it should be understood that the foundation plate 250 need not be present and instead heat could be dissipated to the heat sink 260 via the hollow shaft 240. As shown in FIG. 14k, the foundation plate 250 may comprise projections 252, which are arranged to receive fasteners to attach the frame 234 to the heat sink 260. The fasteners may optionally be bolts. The projections 252 provide a means of dissipating heat from the monofacial photovoltaic elements 216 passing through the thermally conductive layer 219 to the heat sink 260.

The projections 252 may be formed of metal, and may be integrally formed with the foundation plate 250.

Alternatively, the projections 252 and foundation plate 250 may be formed as separate elements. In this arrangement the foundation plate 250 may comprise foundation plate slots which the projections 252 extend through. In this arrangement, the projections may be part of C-members (like item 60 explained in connection with FIG. 12a above). Each C-member may have vertical portions extending through the slots and a horizontal portion in thermal conductivity/contact with the thermally conductive layer 219 or photovoltaic elements 216.

The foundation plate and/or horizontal portion of the C-member provide improved strength to the module 200 and/or frame 234.

As shown in FIG. 14L, the foundation plate 250 may comprise a recess 254 where a lower end of the hollow shaft 240 comprising the electrical terminals 238 is located. The recess 254 is arranged to receive a projection 256 provided on an upper surface of the heat sink plate 262. The projection 256 is best shown in FIG. 14J. The projection 256 comprises a terminal receiving socket 258, which receives the electrical terminals 238 when the foundation plate 250 is placed on top of the heat sink plate 260. The terminal receiving socket 258 is electrically connected to an electrical outlet 261 present on a lower surface of the heat sink plate, as best shown in FIG. 14m. The combination of the recess 254 and projection 256 mean the frame 234 and heat sink 260 are firmly locked mechanically in position, whilst providing a reliable electrical connection to electrical cables running beneath the heat sink plate 260 in use. The combination of the recess 254 and the projection 256 provides a strong seal against water and humidity by making the best use of the weight of the module 200 to tighten the seal. Optionally, and as shown in the depicted example, the projection 256 and recess 254 are square shaped. The square shape strengthens the mechanical lock by preventing undesired sliding or rotation of the module 200 under accidental sheer forces or other types of forces a paver is exposed to.

In the example depicted in FIGS. 14a to 14m, the photovoltaic elements 216 rest horizontally with zero tilt angle. However, it should be understood that the photovoltaic elements 216 may be arranged such that they are tilted with respect to the planar upper surface of the surface screen 218. Optionally, in this embodiment at least the support sheet is corrugated with the photovoltaic elements placed on angled portions of the corrugated sheet. Optionally, in this embodiment, the surface screen 218 is not formed as one piece with the support and thermally conductive layers, and the surface screen is spaced apart from the photovoltaic elements. Optionally, when the support sheet is corrugated, the modules are formed such that they are circular, hexagonal, or octagonal in shape. Advantageously, more solar energy can be harvested by tilted photovoltaic elements in each solar paver module while the upper surface of the surface screen remains planar.

Furthermore, the surface screen of the ninth embodiment may be arranged to rotate like the third, fourth and eight embodiments of the invention. When the surface screen 218 is arranged to rotate in the ninth embodiment, the surface screen must be circular to allow rotation. Furthermore, the fixings 221 must not be present to allow the screen to rotate freely within the frame 234. The frame 234 is fixed with respect to the heat sink 260, and the socket 258 is rotatably mounted on the heat sink by way of a bearing, meaning the socket is allowed to rotate. The electrical terminals snap-fit into the socket 258. Heat can be conducted from the heat conducting layer to the heat sink via the hollow shaft 240. The shaft 240 extends into the projection via an additional recess for receiving the shaft provided in the projection 256, and is connected to the rotatably mounted socket, thereby meaning the shaft can rotate also. Optionally, a shaft extension may be provided upon a lower end of the hollow shaft 240 which extends below the projection 256. Alternatively, there may be no shaft extension and the shaft itself may extend below the projection 256.

The shaft, the shaft extension and/or socket may be connected to a crank or drive mechanism. The shaft 240 may further dissipate heat by the provision of fins or concentric rings. In a variation of this arrangement, the frame 234 may be completely hollow and locked mechanically to the heat sink via two interlocking members, where one of the two interlocking members is provided on an underside of the frame 234 and the other is provided on an upper surface of the heat sink 260.

As an alternative to the rotational mechanism described above, the rotational mechanism of the third, fourth and eighth embodiments of the invention may be incorporated in the module of FIGS. 14a to 14m, for example, in optional embodiments when the photovoltaic elements 216 are tilted relative to the planar upper surface of the module 200.

The hollow shaft 240 may comprise external and internal shafts. The internal shaft may be releasably connected to the external shaft such that the internal or external shaft may be removed to access a protection/bypass diode electrically connected to the photovoltaic elements 216. The internal shaft may be releasably connected to the external shaft by way of a threaded arrangement.

Alternatively, the external shaft may be releasably connected to the internal shaft such that the internal or external shaft may be removed to access a protection/bypass diode electrically connected to the photovoltaic elements 516.

The external shaft may be releasably connected to the internal shaft by way of a threaded arrangement.

The heat sink 260 of FIGS. 14a to 14.M may be connected to multiple frames supporting photovoltaic elements.

With reference to FIG. 15, there is shown part of a paving module 500, which may be incorporated into the embodiment of FIGS. 14a to 14m. Specifically, the part 500 comprises a frame 534, a piece 535 and a shaft 540 with electrical terminals 538 that may be used in the embodiment of FIGS. 14a to 14m as an alternative to the frame 234, piece 235 and shaft 240. The shaft 540 and electrical terminals are formed such that they may rotate when inserted into the socket 258 in the manner described in the preceding paragraph. In this piece 535, the photovoltaic elements 516 are tilted with respect to the upper surface of the surface screen 536.

The piece 535 comprises the transparent surface screen 536, which encloses the photovoltaic elements 516, and optionally is formed of transparent polymer, such as epoxy, which is cast over the photovoltaic elements 516. Each photovoltaic element is provided upon a support 517, which optionally provides electrical insulation and shock absorption under excessive mechanical overloads to avoid fracture of the photovoltaic element. The support optionally comprises silicone. Optionally, additives which act to improve the thermal conductivity of the support 517 are provided in combination with the silicone in each support 517. The supports 517 are themselves provided upon a corrugated sheet 520 in this example. The corrugated sheet 520 is typically formed of metal and in this example comprises angled portions upon which the supports 517 rest.

The corrugated sheet 520 is itself provided upon a polymer layer 522, which typically comprises a polymer such as epoxy, and optionally additives to improve the thermal conductivity of the polymer layer. The polymer layer 522 is optionally provided upon a thermally conductive layer 523, which typically comprises a metal. Optionally, the thermally conductive layer 553 is formed of a metal plate. Optionally, the thermally conductive layer 523 may be bonded to the corrugated sheet 520 along its periphery to enhance thermal conduction

A hollow shaft 540 depends from the thermally conductive layer 553, and has located therein electrical terminals 538. Electrical connections connected to the photovoltaic elements extend from the photovoltaic elements through the hollow shaft 540 to the electrical terminals 538. When attached to the heat plate 260, the shaft may extend beyond the heat plate 260. Optionally, a shaft extension may be provided.

The hollow shaft 540 may comprise external and internal shafts. The internal shaft may be releasably connected to the external shaft such that the internal or external shaft may be removed to access a protection/bypass diode electrically connected to the photovoltaic elements 516. The internal shaft may be releasably connected to the external shaft by way of a threaded arrangement.

Alternatively, the external shaft may be releasably connected to the internal shaft such that the internal or external shaft may be removed to access a protection/bypass diode electrically connected to the photovoltaic elements 516. The external shaft may be releasably connected to the internal shaft by way of a threaded arrangement.

Suitable additives to improve the thermal conductivity of the supports 517 and polymer layer 522 include one or more of the following: carbon-based fillers such as graphite particles or graphite nanoplatelets (GNPs); and metallic or ceramic fillers such as aluminium oxide, aluminium nitride and silver. Optionally, each support comprises silicone with 50% to 60% of its content being composed of a hybrid filler comprising large-sized aluminium oxide and small-sized aluminium nitride particles.

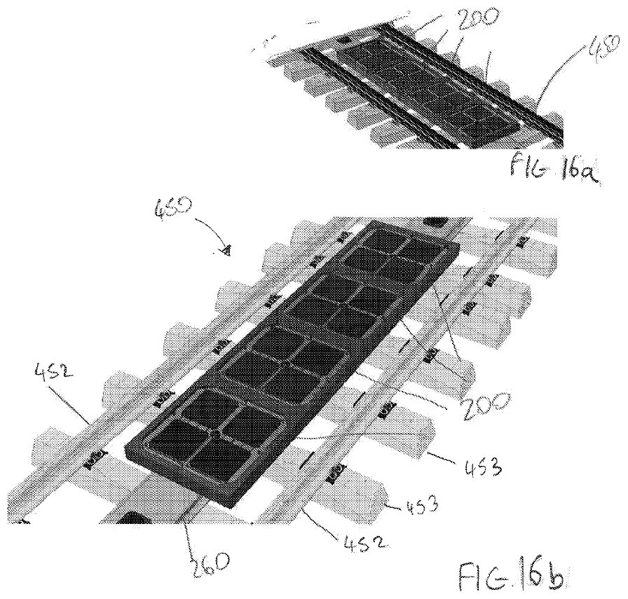

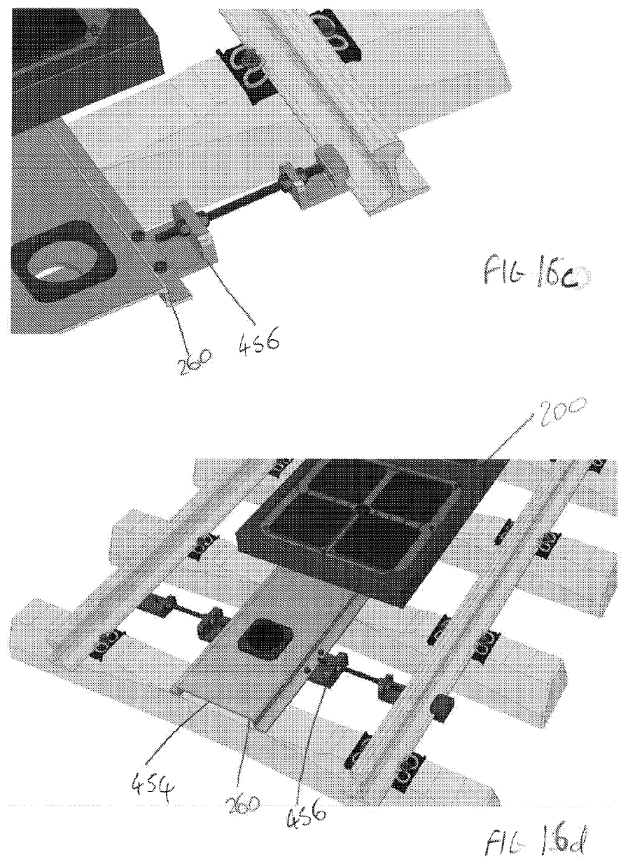

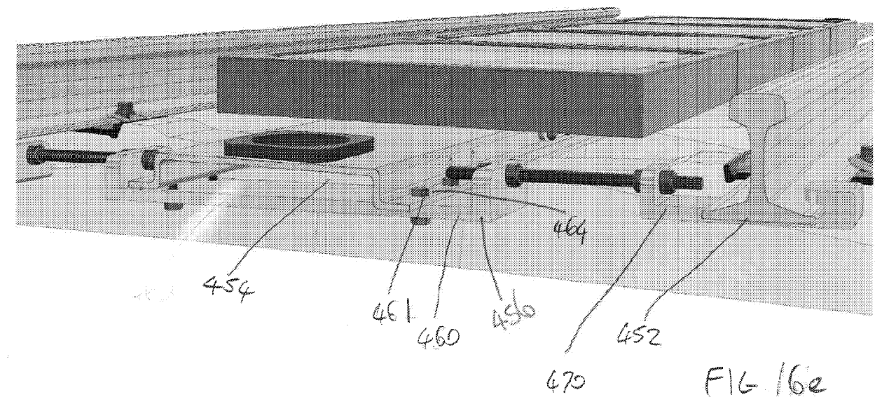

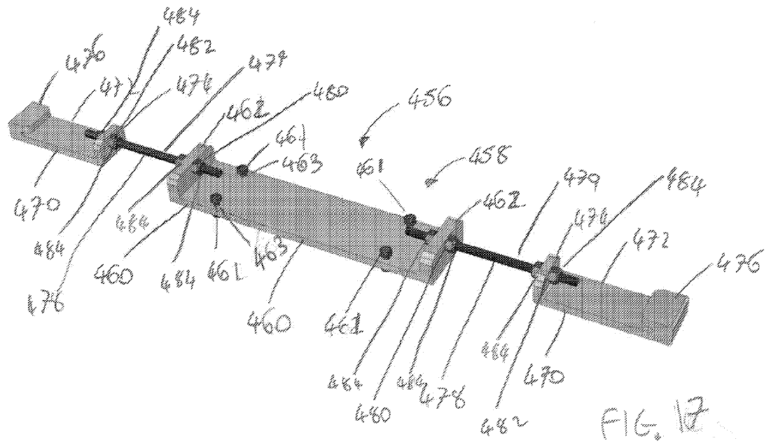

With reference to FIGS. 16a to 16e, there is shown an array of solar paving modules 200 in accordance with the ninth embodiment of the invention fixed in position upon a railway 450. As shown, the railway comprises two parallel rails 452 which are supported upon horizontal sleepers 453. The array of solar paving modules 200 is provided between the two rails 452. As depicted the modules 200 are connected end to end such that they extend in a line which extends in the same direction as the railway 450. As best shown in FIG. 16e, as the modules 200 are connected end to end a channel 454 is formed by the heat sinks 260 of the modules. Conduits or electrical wires connected to the modules can advantageously be run through this channel 454. Alternatively, a single heat sink 260 may be provided upon which multiple frames and photovoltaic elements are supported, and the channel may extend below the single heat sink 206.

Each module 200 is held in place between the rails by a fastening member 456. As shown each fastening member 456 is secured to each paving module 200 and to a foot portion of each parallel rail 452.

The fastening member 456 used in FIGS. 16a to 16e is shown in more detail in FIG. 16. As shown the fastening member 456 comprises a module attachment portion 458 which comprises a base plate 460 and base plate flanges 461 provided at each end of the base plate 460. As depicted in FIG. 16e in use the heat sink 260 of a module 200 is secured to the base plate 460 with base plate securing fasteners 461 which extend through base plate apertures 463 provided in the base plate 460. In the depicted example, corresponding heat sink apertures 464 are provided in the heat sink 260.

The base plate 460 is secured to each rail 452 via rail securing components 470 attached to respective base plate flanges 462 of the base plate 460 (as shown in FIG. 16e and FIG. 17). Each rail securing component 470 comprises a rail securing plate 472, which has a securing component flange 474 at one end and a rail securing recess 476 at the other end. As best shown in FIG. 16e in use the rail securing recess 476 receives an outer portion of the foot of each rail 452 to secure the rail securing component to the rail 452. Each rail securing component 470 is attached to a respective base plate flange 462 via a respective nut and bolt arrangement 478. Each of the nut and bolt arrangements 478 comprises a bolt 479 which extends through a base plate flange aperture 480 provided in one of the base plate flanges 462 and a corresponding securing component flange aperture 482 provided in the securing component flange 474. The bolt 479 is secured in position via nuts 484. The nuts 484 can be loosened and tightened to control the force applied by the securing component recess 476 on the foot of the each rail 452.

An advantage of the arrangement of FIGS. 16a to 16e is that no extra structural supports are required. This in contrast to prior arrangements which require additional supports to withstand shockwaves from high speed trains. Furthermore, in the arrangement of the present invention, the modules can be installed along the whole length of the track, rather than just above railway sleepers like in prior arrangements. Furthermore, advantageously the solar paving modules of the arrangement of FIGS. 16a to 16e can be easily cleaned with a rolling train vehicle equipped with a simple brush-and-spray system. Additionally, the arrangement of FIGS. 16a to 16e can dissipate heat efficiently by convection as a large sink area is provided.

### INDUSTRIAL APPLICABILITY

The invention can be used in the vast areas of sunny pedestrian walkways and yards found in cities, towns, and villages in many regions of the world. Traditional solar panels are not walkable, but the solar paving modules of the present invention allow these spaces to become potential sources of power. The solar paving modules of the present invention can withstand heavy weight or mechanical loads of people, bikes, and the occasional loading of lightweight slow-speed vehicles. Unlike conventional solar panels, which are normally mounted on tilted frames or supported with an underneath clearance to allow for air flow, and depend on natural air flow for cooling, the solar paving modules 10 of the present invention have a non-glass light transmitting surface screen 18 to reduce heat absorption and in-built heat sinks to carry away the heat that is generated by the photovoltaic elements 16.

The frame 12 and solar paving module 10 can be of any suitable shape. The shape is not limited to the illustrated examples. For example it can be of a circular, triangular, square, rectangular, hexagonal, polygonal, or any other regular or irregular shape.

The surface screen 18 is made of a transparent material of suitable optical characteristics. The surface screen provides sufficient mechanical strength, durability, inherent (or added) anti-slip property, inherent (or added) anti-scratch property, and inherent (or added) hydrophobic (dust and water repelling) property. The surface screen material is selected to satisfy the required light transmittance requirements. Its degree of transparency and colour can vary from partially opaque to full transparent depending on the installation location requirement. The surface screen 18 also serves as part of the passive cooling system integrated in the solar paving module. For this reason the surface screen 18 is optionally made of a clear polymer. A polymer-based resin material, for example an epoxy resin manufactured for flooring purposes, has been found to be particularly beneficial, since it traps less heat than the conventional glass material. The use of an epoxy material offers several advantages over glass. Firstly, to withstand the loads a paver needs to withstand, a significantly thick layer of glass must be used at an associated high cost. Secondly, smooth glass is slippery and cannot be used as a walking surface, hence an additional process of surface preparation has to be applied to add a texture to make it suitable for walking on, at the expense of manufacturing time and product cost. Thirdly, glass has a greenhouse effect, it traps heat beneath it which leads to increased temperatures of the photovoltaic elements and hence reduced power production and reduced life span of the photovoltaic elements. Polymer-based resin (e.g. epoxy) surface structures, on the other hand, are of lower cost and easier to manufacture. They have better thermal performance, since they do not trap heat and they dissipate it much better than glass.

The surface screen 18 itself can be of circular, square, or polygonal shape and rests on the frame such that the border 34 of the frame 12 encloses the screen from all sides except the upper face. However, where a tracking disc 90 is not required, in one variation the surface screen 18 can extend above the recess 32 in the frame 12 and cover the upper surface 36 of the border 34.

The power generating element 14, which is encapsulated in the surface screen 18, can comprise a monocrystalline, polycrystalline, amorphous, or another form of photovoltaic element 16 or a number of such elements 16 connected together in series or parallel or a combination of series-parallel connections to generate a certain amount of power by converting incident light to electricity. The photovoltaic elements 16 can be of different sizes and shapes; they can be bifacial (i.e. generating power by light incident on both upper and lower faces) or single-face.

The frame 12 can comprise one layer; or two or more interlocking or dove-tailed layers, as illustrated in FIGS. 10a and 10b. The frame 12 can be made of one or more of the following materials: concrete, plastic, plastic-reinforced concrete, fibre-reinforced plastic, fibre-reinforced concrete, steel/steel alloy-reinforced plastic, steel/steel alloy-reinforced concrete, or other composite material. The frame can be made of a composite construction which can include two or more of the aforementioned materials.

The heat sink 60, and the metal components which make up the heat sink 60, such as the heat conducting support surface 26, the heat sink plate 62 and the heat sink anchor 64, serve a number of purposes.

Firstly, the heat sink 60 acts as a heat dissipation element discharging the heat generated by the power generation process by means of geothermal cooling, thereby limiting the operating temperature of the photovoltaic element 16. In general higher temperatures may lead to less efficient power generation. In certain photovoltaic technologies a higher temperature of the photovoltaic element 16 above 45° C. means almost 0.5% less power production for each degree above 45° C. Cooling is therefore essential when installing modules 10 in very sunny places, and is generally advantageous in all locations. The passive cooling of the present invention, which is based on geothermal cooling principles, solves this problem by dissipating excess heat to the soil.

Secondly, the heat sink 60 increases the mechanical strength of the solar paving module 10, since the metal components act as reinforcing elements.

Thirdly, the heat sink 60, and in particular the heat sink anchor 64 or ground plates 80, can be used to fix or mount the paver firmly in the ground. This further enables a firm connection with the underlying soil for effective heat management. The heat sink 60 can take many shapes and designs as illustrated in the above embodiments.

The solar paving module 10 can include an electronic junction box (not shown) or can have a separate electronic junction box (not shown). This can be a weatherproof sealed box which is placed underneath each paver. Alternatively a single junction box can serve a group of pavers. The junction box can house electronics, for example a bypass diode(s) and/or blocking diode(s) as appropriate. The bypass diode can bypass a paver if it gets shaded, thus protecting the encapsulated PV cells from thermal damage by hotspots. A blocking diode is needed in each string of pavers to block current flow in reverse.

Each solar paving module 10 has at least one electrical connector 22, 23, optionally comprising terminals 23a, 23b arranged in pairs, each pair comprising a positive terminal and a negative terminal. The terminals connect each paver to one or more adjacent pavers. Optionally the connectors are weatherproof, and are connected internally to appropriately insulated wires.

A number of solar paving modules 10 are grouped together in strings of series, parallel or series-parallel connected units to build up the required system power and voltage outputs. The solar paving modules 10 together form a paving construction.

The terminals of the connector 22 of the solar paving module 10 can be connected to an electronic converter or microinverter to convert DC to AC and to connect to the grid and/or loads. In another embodiment the terminals of the connector 22 of the solar paving module 10 at the end of each string are connected to an electronic converter or microinverter to convert DC to AC and to connect to the grid and/or loads. The microinverters are all connected in parallel at their AC side to feed the grid and/or local loads. Alternatively, strings of series connected solar paving modules 10 may be connected in parallel through a combiner box housing connection points and protection devices, and the terminals of the combined system are then connected to an aggregate electronic converter converting DC to AC (string/central inverter).

In both types of electric interface system described above, electronic converters and control circuitry may be housed either outdoors in protective and/or weatherproof enclosures of high IP (Ingress Protection) number or indoors. Battery banks can be optionally connected to either type of electric interface systems through appropriate control and charging circuitry, which can be similar to traditional solar PV systems. Batteries may be housed in protective enclosures of high IP number, appropriately buried in soil, or placed indoors in a protected environment.

In one method for mounting the solar paving modules 10 on the ground, the solar paving modules 10 are laid against one another in an array over a bedding of sand and gravel, in a method similar to that used for traditional paving stones. This method allows simple replacement of a solar paving modules 10 in case of malfunction, i.e. a single solar paving module 10 can be easily lifted up and replaced. However, in contrast to traditional paving stone installation, the solar paving modules 10 of the invention may also be fixed to the bedding via the heat sink anchors 64 or ground plates 80. This provides increased strength and rigidity of the pavement, i.e. the paving construction.

In some embodiments, an interlocking means may be provided. For example in the embodiment of FIG. 11 the male connectors 22a and female connectors 22b serve as structural interlocks as well as electrical connectors. Such an interlocking mechanism adds further rigidity to the assembled pavement. In this case, no connecting wires are required to connect adjacent solar paving modules 10. The bypass/blocking diode(s) are connected across the photovoltaic element terminals internally in the frame 12 in a junction box (not shown).

When there is no structural interlocking mechanism, for example in the embodiments of FIG. 1 or FIG. 12a, the electric terminals of the solar paving modules 10 can be brought out through the bottom face of the frames 12 (out of the junction box if present) and connected to the adjacent solar paving modules 10 via high IP connectors. The bottom face of the frame 12 can have formed channels (not shown) to house in full or in part the connecting terminals. These channels can be optionally of curved shapes to house a longer length of connecting wire to allow lifting the solar paving module 10 easily during maintenance or replacement. The channels also house the connecting plugs safely and securely house away from the mechanical loads.

An advantage of the two component frame 12 illustrated in FIGS. 10a and 10b is that at least part of the frame can be made of recycled plastic to boost the environmental impact and reduce the plastic landfill. This way, not only the structure is reinforced, but also—if widely deployed—vast areas of walkable pathways can be a destination for bulk amounts of recycled plastic.

In any of the embodiments, regardless of whether the frame 12 is entirely made of concrete or has a concrete layer, plastic granules can be added to the concrete mix for reinforcement. The granules can be of recycled plastic.

The presence of bypass diode(s) in every solar paving module 10 means that even in case of photovoltaic element failure or malfunction, the module can be successfully bypassed and ceases to generate power while the rest of the paving module string is fully functional. The same applies when one or more modules 10 get shaded, although the bypass is of a temporary nature in this case and ceases when the shading ceases.

The invention offers the advantage that the photovoltaic element 16 can be tilted to the optimal tilt-angle at the location of installation, unlike existing solar floor pavers in which the photovoltaic element is fixed in a horizontal position.

In the embodiment with a rotatable tracking disc 90 the surface screen 18 and the embedded photovoltaic elements 16 can be made to rotate around the vertical axis in small steps inside the paver frame 12 to provide variable orientation of the tilted rows of photovoltaic elements 16 rows to track the sun during the day. The reliable long-life rotation mechanism is placed underneath the modules 10 to manage the small step-wise orientation of surface screens. It can contribute to the overall structural strength of the paver system and also contribute to enhanced heat dissipation to ground. In practice, it may be desired to rotate the tracking disc 90 to 100 degrees over a period of 6 hours, during which there is useful sunshine. This requires minimal energy, because the speed of rotation is less than 1 degree every 3 minutes.

Bifacial photovoltaic elements 16, which can utilize light from both sides, can be used in the modules 10. In such cases, flat or curved collectors/reflectors can be embedded to the side walls and bottom section of the recess 32 in the frame 12 below the level of the bifacial photovoltaic element 16 to direct as much incident light as possible to the lower surface of the bifacial photovoltaic cells. The use of bifacial photovoltaic cells can significantly increase the electric yield, since power can be generated by light incident on both faces.

The support and thermal conducting layers described in connection with the ninth embodiment above may be incorporated in the other embodiments of the invention. For example, they may be incorporated in a solar paving module with photovoltaic elements which are tilted with respect to the upper surface of the surface screen, like in the embodiment of FIG. 1.

The modules may have hexagonal or octagonal shaped frames and surface screens in the array of modules shown in FIGS. 15a to 15e. The frames of the modules may be formed of high density polyurethane or hard plastic.

In the embodiments, FIGS. 12 and 15, the one or more ground plates of the heat sink extend beyond the frame. Optionally, the ground plates extend beyond a base of the frame. Optionally, the heat sink is adapted to be embedded in a substrate below the frame; and the ground plate is adapted to be embedded in substrate below the frame.

The heat sink of FIGS. 14a to 14.M may optionally be connected to multiple frames supporting photovoltaic elements.

The level of thermal conductivity enhancement in the polymer layer and silicone sheets depends on the percent filler/additive content. For instance, epoxy thermal conductivity can be boosted more than 10-fold with 50-60% content of hybrid filler composed of large-sized aluminium oxide and small-sized aluminium nitride particles. This would make the thermal conductivity of the epoxy layer significantly higher than glass.

One benefit of the claimed subject matter is enhanced efficiency in hot regions. The optional inclusion of polymers like epoxy for example provide better heat management properties, are more cost effective and have better mechanical durability than known solutions. The claimed subject matter also provides enhanced thermal conductivity through the heat sink in each paver. The heat sink optionally provides advantages in terms of mechanical strengthening of the surface screen and frame structures as well as firm mounting to the ground or base.

Advantageously, the support layer may act as a shock absorber to avoid fracture of the power generating module in case of sudden force or overload applied to the surface screen 235 or 535.

Modifications and variations are possible without departing from the scope of the invention. In particular the invention is not limited to the particular shapes and materials described above.

1-33. (canceled)

34. A solar paving module comprising:
a frame,
a power generating element comprising at least one photovoltaic element supported in the frame,
a light transmitting surface screen covering the electrical power generating element and having a planar upper surface, and
an electrical connector connected electrically to the power generating element,
wherein the solar paving module comprises a heat sink in thermal connectivity with the power generating element, the heat sink comprising a heat sink plate and two ground plates connected to the heat sink plate and forming a heat sink anchor,
wherein each of the ground plates depends from a side of the heat sink plate.

35. The solar paving module of claim 34, wherein the ground plates extend beyond the frame.

36. The solar paving module of claim 34, wherein the heat sink plate is substantially parallel to the planar upper surface of the light transmitting surface screen and the ground plates extend substantially perpendicular to the heat sink plate.

37. The solar paving module claim 34, wherein the heat sink plate and the ground plates comprise one or more of:
a single folded plate of heat conducting material selected from metallic material, aluminium and alloys thereof, non-metallic material, and a mixture of metallic material and non-metallic material;
one or more mesh panels of metal; and
one or more plates of metal and one or more mesh panels of metal.

38. The solar paving module of claim 34, wherein the heat sink plate and the ground plates are integrally formed as a single piece.

39. The solar paving module of claim 34, wherein the heat sink plate and the one or more ground plates are arranged in a C-shaped configuration when viewed in cross-section.

40. The solar paving module of claim 34, wherein the heat sink comprises a shaft, the shaft extending between the power generating element and the heat sink plate.

41. The solar paving module of claim 34, wherein the frame encloses the power generating element and at least a portion or the entirety of the screen, wherein an underside of the frame comprises a first interlocking member arranged to interlock with a second interlocking member provided on an upper surface of the heat sink plate.

42. The solar paving module of claim 34, wherein the surface screen and the power generating element are part of a tracking disc which is circular in plan and arranged for rotation relative to the frame about a rotational axis perpendicular to the planar upper surface of the light transmitting surface screen.

43. The solar paving module of claim 42, further comprising a driver for driving rotation of the tracking disc, the driver comprising a vertical drive shaft rotationally driven by an external actuator.

44. The solar paving module of claim 43, wherein the external actuator comprises one or more drive rods or drive cables offset from the rotational axis of the tracking disc and connected by a crank to the vertical driveshaft.

45. A paving construction comprising a plurality of solar paving modules according to claim 34, the electrical connector of each of the plurality of solar paving modules being connected to the electrical connector of another of the plurality of solar paving modules.

46. A paving construction comprising a plurality of solar paving modules according to claim 43 arranged in a line and an electric motor, wherein the external actuator comprises a drive rod offset from the rotational axes of each of the tracking discs and connected by a respective crank to each vertical drive shaft, wherein the drive rod is drivably coupled to the electric motor.

47. A paving construction comprising a plurality of solar paving modules according to claim 43 arranged in a line and an electric motor, wherein the external actuator comprises a pair of drive cables, each offset on opposite sides of the rotational axes of each of the tracking discs and connected by a respective crank to each vertical drive shaft, wherein the drive cables are drivably coupled to the electric motor.

48. A railway comprising:
two parallel rails;
at least one paving module in accordance with any of claims 1 to 9 located between the rails; and
at least one fastening member arranged to attach the at least one paving module to at least one of the rails.
